(19) United States
(12) Patent Application Publication
(10) Pub. No.: US 2004/0238209 A1
(43) Pub. Date: Dec. 2, 2004

(54) Multilayer wiring board, method of manufacturing the wiring board and substrate material for the wiring board

(75) Inventors: Shinji Yuri, Aichi (JP); Tomoe Suzuki, Aichi (JP); Kazuhisa Sato, Aichi (JP); Kozo Yamazaki, Gifu (JP)

Correspondence Address: SUGHRUE, MION, ZINN, MACPEAK & SEAS, PLLC, 2100 Pennsylvania Avenue, N.W., Washington, DC, 20037-3202, US

(73) Assignee: NGK SPARK PLUG CO., LTD

(21) Appl. No.: 10/606,326

(22) Filed: Jun. 26, 2003

(30) Foreign Application Priority Data
Jun. 27, 2002 (JP) 2002-187255

(51) Int. Cl. H05K 1/09

(52) U.S. Cl. 174/257; 174/262; 174/264; 29/846

(57) ABSTRACT

A multilayer wiring board comprises a metal substrate having first and second main surfaces, a copper coating applied to at least one of the first and second main surfaces of the metal substrate and having a roughened surface, and an insulating resin layer formed on the roughened surface of the copper coating. The multilayer wiring board may further comprises a wiring layer arranged on the insulating resin layer and a via extending through the insulating resin layer between the copper coating and the wiring layer.

### BACKGROUND OF THE INVENTION

The present invention relates to a multilayer wiring board, a method of manufacturing the multilayer wiring board and a substrate material for the multilayer wiring board. More specifically, the present invention relates to the technique of providing good interfacial adhesion between a metal substrate and an insulating resin layer of the multilayer wiring board.

Japanese Laid-Open Patent Publication No. 2000-101245 discloses a multilayer resin printed wiring board, comprising a metal substrate (as a core) and alternating insulating resin layers and wiring layers (so-called build-up layers) arranged on both surfaces of the metal substrate. In this type of printed wiring board, a blind-via is often formed in the insulating resin layer to establish electrical connection between the metal substrate and the wiring layer so that the metal substrate can also function as a ground layer or a power-supply layer.

Further, the wiring layers are generally made of copper (in most cases, electrolytic copper). On the other hand, the metal substrate can be made of copper, a copper alloy or any other metal or alloy, and is generally formed by metal rolling rather than plating so as to be larger than several tens of micrometers in thickness (e.g. have a thickness of 100 μm or larger).

### SUMMARY OF THE INVENTION

It is difficult to secure good interfacial adhesion of the insulating resin layers to such a rolled metal substrate without giving any surface treatment to the metal substrate. When the interfacial adhesion between the metal substrate and the insulating resin layers is insufficient, there arises a possibility that the insulating resin layers become separated from the metal substrate. This results in insulation failure.

In the case of forming the blind-via by defining a blind hole in the insulating resin layer and coating the blind hole with an electroless copper plating, it is also difficult to secure good interfacial adhesion of the blind-via to the metal substrate. When the interfacial adhesion between the metal substrate and the blind-via is insufficient, there arises a possibility that the blind-via becomes separated from the metal substrate. This results in defective electrical conduction.

In order to avoid these problems, it is conceivable to give chemical surface roughening treatment (such as black-oxide coating, acid treatment or microetching) that is conventionally given to the electrolytic-copper wiring layers, to the metal substrate so as to form a roughened surface on the metal substrate for improvement in the adhesion between the metal substrate and the insulating resin layers and between the metal substrate and the blind-via.

However, the rolled metal substrate is more closely packed than the electrolytic-copper wiring layers. Even when the surface roughing treatment is performed under the same conditions, the rolled metal substrate cannot obtain a desired roughened surface. In the case of the metal substrate being made of a metal alloy (such as a Fe—Ni alloy) other than copper alloys, it is doubtful whether the above known treatment is effective in surface roughening the metal substrate.

It is therefore an object of the present invention to provide a multilayer wiring board that is capable of attaining good adhesion between a metal substrate and an insulating resin layer and, when a blind-via is formed in the insulating resin layer for electrical connection between the metal substrate and a wiring layer, is also capable of attaining good adhesion between the metal substrate and the blind-via.

It is also an object of the present invention to provide a method of manufacturing the multilayer wiring board and a substrate material for the multilayer wiring board.

According to a first aspect of the invention, there is provided a multilayer wiring board, comprising: a metal substrate having first and second main surfaces; a copper coating applied to at least one of the first and second main surfaces of the metal substrate and having a roughened surface; and an insulating resin layer formed on the roughened surface of the copper coating.

According to a second aspect of the invention, there is provided a multilayer wiring board, comprising: a metal substrate having first and second main surfaces and defining therein a through hole extending between the first and second main surfaces; a copper coating applied to the first and second main surfaces of the metal substrate and an inner surface of the through hole and having a roughened surface; a plurality of insulating resin layers and wiring layers formed on the roughened surface of the copper coating to be located on the first and second main surfaces of the metal substrate, the insulating resin layers being interposed between the copper coating and the wiring layers or between the copper coating and the wiring layers and between the wiring layers; a resin filler filled in the through hole; a first via extending through the insulating resin layer between the copper coating and the wiring layer; and a second via extending through the resin filler and the insulating resin layers between the wiring layer located on the first main surface and the wiring layer located on the second main surface while being kept insulated from the metal substrate.

According to a third aspect of the invention, there is provided a method of manufacturing a multilayer wiring board, comprising: preparing a metal substrate having first and second main surfaces; applying a copper coating to at least one of the first and second main surfaces of the metal substrate; surface roughening the copper coating to form a roughened surface on the copper coating; forming an insulating resin layer to the roughened surface of the copper coating; and arranging a wiring layer on the insulating resin layer.

According to a fourth aspect of the invention, there is provided a method of manufacturing a multilayer wiring board, comprising: preparing a metal substrate having first and second main surfaces; defining a through hole in the metal substrate; plating the metal substrate with copper to apply a copper coating to the first and second main surfaces of the metal substrate and an inner surface of the through hole; surface roughening the copper coating to form a roughened surface on the copper coating; forming insulating resin layers on the roughened surface of the copper coating so as to be located on both the first and second main surfaces of the metal substrate; arranging wiring layers on the respective insulating resin layers; filling a resin filler in the through hole; providing a first via extending through the insulating resin layer between the copper coating and the wiring layer; and providing a second via extending through the resin filler and the insulating resin layers between the wiring layer located on the first main surface and the wiring layer located on the second main surface while being kept insulated from the metal substrate.

According to a fifth aspect of the invention, there is provided a substrate material for a multilayer wiring board, comprising: a metal substrate being a rolled plate of Fe—Ni alloy formed with a thickness of 150 μm or larger and having first and second main surfaces; and a copper coating applied to at least one of the first and second main surfaces of the metal substrate, having a roughened surface and being formed with a thickness of 5 μm or larger.

According to a sixth aspect of the invention, there is provided a substrate material for a multilayer wiring board, comprising: a metal substrate being a rolled plate of Fe—Ni alloy formed with a thickness of 150 μm or larger, having first and second main surfaces and defining therein a through hole extending between the first and second main surfaces; and a copper coating applied to the first and second main surfaces of the metal substrate and an inner surface of the through hole and having a roughened surface.

### BRIEF DESCRIPTION OF THE DRAWINGS

FIG. 1 is a partially enlarged cross-sectional view of a multilayer wiring board according to a first embodiment of the present invention.

FIGS. 2 to 5 are schematic illustrations of the processes of preparing a metal substrate and defining a through hole in the metal substrate according to the first embodiment of the present invention.

FIG. 6 is a schematic illustration of the process of applying a copper coating to the metal substrate according to the first embodiment of the present invention.

FIG. 7 is a partially enlarged cross-sectional view of the interface between the metal substrate and the copper coating before the process of surface roughening treatment.

FIG. 8 is a partially enlarged cross-sectional view of the interface between the metal substrate and the copper coating after the process of surface roughening treatment.

FIGS. 9 to 15 are schematic illustrations of the processes of forming insulating resin layers, wiring layers and blind- and through-vias according to the first embodiment of the present invention.

FIGS. 16 to 19 are schematic illustrations of the processes of preparing a metal substrate, applying a copper coating to the metal substrate and defining a through hole in the metal substrate according to a second embodiment of the present invention.

FIG. 20 is a partially enlarged cross-sectional view of a multilayer wiring board according to a modification of the embodiment.

### DESCRIPTION OF THE EMBODIMENTS

A multilayer wiring board according to one exemplary embodiment of the present invention comprises a metal substrate having first and second main surfaces, a copper coating applied to at least one of the first and second main surfaces of the metal substrate and having a roughened surface, an insulating resin layer formed on the roughened surface of the metal substrate, and a wiring layer arranged on the insulating resin layer. The wiring board desirably comprises a blind-via (as a first via) formed in the insulating resin layer to extend between the copper coating and the wiring layer. In the case where the copper coating is applied to both the first and second main surfaces of the metal substrate, the wiring board may comprises a second insulating resin layer formed on the roughened surface of the copper coating to be located on the main surface opposite to the main surface on which the first mentioned insulating resin layer is located, and a second wiring layer arranged on the second insulating resin layer. In this case, it is desirable to define a through hole in the metal substrate and to apply the copper coating to an inner surface of the through hole as well as both the main surfaces of the metal substrate so that the wiring board comprises a resin filler filled in the through hole and a through-via (as a second via) formed in the resin filler and the insulating resin layers to extend between the wiring layer located on the first and the wiring layer located on the second main surfaces while being kept insulated from the metal substrate.

In such a structure, the roughened surface of the copper coating serves as an anchor for anchoring thereon the first and second insulating resin layers formed adjacently to the copper coating so as to improve the adhesion of the insulating resin layers to the metal substrate. This makes it possible to prevent the insulating resin layers from becoming separated from the metal substrate and to secure proper electrical insulation. The roughened surface of the copper coating also serves as an anchor for anchoring thereon the blind-via so as to improve the adhesion of the blind-via to the metal substrate and to prevent the blind-via from becoming separated from the metal substrate for proper electrical conduction. Although the copper coating is interposed between the metal substrate and the blind-via, the copper coating has good electric conductivity and does not interfere with the electrical conduction between the metal substrate and the blind-via. The roughened surface of the copper coating produces such an anchoring effect on the resin filler so as to improve the adhesion of the resin filler to the metal substrate. This also makes it possible to prevent the resin filler from becoming separated from the metal substrate and to secure proper electrical insulation.

The wiring board may comprise one or more additional insulating resin layers between the copper coating and the first insulating resin layer and/or between the copper coating and the second insulating layer. The wiring board may further comprise one or more wiring layer each arranged between any adjacent insulating resin layers. In other words, the insulating resin layers and the wiring layers can be located on either one of the first and second main surfaces of the metal substrate or on both the first and second main surface of the metal substrate, and the insulating resin layers can be interposed between the copper coating and the wiring layer or between the copper coating and the wiring layer and between the wiring layers.

The above-structured wiring board can be manufactured by: preparing the metal substrate; applying the copper coating to the metal substrate; surface roughening the copper coating to define the roughened surface on the copper coating; forming the insulation resin layer on the roughened surface of the copper coating; and then arranging the wiring layer on the insulating resin layer. In the case of providing the insulating resin layers and the wiring layers on both the first and second main surfaces of the metal substrate and providing the resin filler, the blind-via and through-via, the wiring board can be manufactured by: preparing the preparing the metal substrate; defining the through hole in the metal substrate; plating the metal substrate with copper to apply the copper coating to both the first and second main surfaces of the metal substrate and an inner surface of the through hole; surface roughening the copper coating to define the roughened surface on the copper coating; forming the insulating resin layers on the roughened surface of the copper coating so as to be located on both the first and second surfaces of the metal substrate; arranging the wiring layers on the respective insulating resin layers; filling the resin filler in the through hole; providing the blind-via extending through the insulating resin layer between the copper coating and the wiring layer; and providing the through-via extending through the resin filler and the insulating resin layers between the wiring layer located on the first main surface and the wiring layer located on the second main surface while being kept insulated from the metal substrate.

Herein, the material and forming process of each board component will be explained below.

The material of the metal substrate can be selected as appropriate according to its electrical conductivity, cost, machinability and the like. The metal substrate is desirably made of any of copper, copper alloys, and any other metals and alloys. Examples of the copper alloys usable for the metal substrate include aluminum bronze (Cu—Al alloy), phosphor bronze (Cu—P alloy), brass (Cu—Zn alloy) and cupronickel (Cu—Ni alloy). Examples of the metals usable for the metal substrate include aluminum, iron, chrome, nickel and molybdenum. Examples of the metal alloys usable for the metal substrate include stainless steel (iron alloys, such as Fe—Cr alloys and Fe—Cr—Ni alloys), Invar (Fe—Ni alloy with a Ni content of 36%), a so-called 42 alloy (Fe—Ni alloy with a Ni content of 42%), a so-called 50 alloy (Fe—Ni alloy with a Ni content of 50%), nickel alloys (such as Ni—P alloys, Ni—B alloys and Ni—Cu—P alloys), cobalt alloys (such as Co—P alloys, Co—B alloys and Co—Ni—P alloys) and tin alloys (such as Sn—Pb alloys and Sn—Pb—Pd alloys). Among the above metals and alloys, any of the Fe—Ni alloys (such as Invar, 42 alloy and 50 alloy) is preferably used. The Fe—Ni alloy has a smaller thermal expansion coefficient than that of copper. With the metal substrate made of such a Fe—Ni alloy, it is possible to allow the wiring board to be of low expansion. The Fe—Ni alloy also has good electric and thermal conductivity although it is lower than that of copper. It is also possible to allow the metal substrate to suitably function as a ground layer or a power-supply layer by providing the blind-via, and possible to achieve efficient heat radiation. As a result, the metal substrate can be rated as a high-value added component.

The thickness of the metal substrate is not particularly restricted, and is generally controlled to 150 μm or larger, preferably 150 to 500 μm, more preferably 150 to 300 μn. When the thickness of the metal substrate is smaller than 150 μm, the metal substrate becomes readily wrinkled and damaged with folds due to its low rigidity during manufacturing. Such deterioration of handleability results in lowered manufacturing yield. When the thickness of the metal substrate exceeds 500 μm, the metal substrate can attain sufficient rigidity but becomes too large in thickness and too low in machinability. In view of cost and productivity, the metal substrate is preferably formed by rolling to be in the form of a plate having a thickness of 150 μm or larger.

The material and forming process of the wiring layers can be selected as appropriate according to its electrical conductivity and adhesion with the insulating resin layer. Examples of the material of the wiring layers include copper, copper alloys, nickel, nickel alloys, tin and tin alloys. Each wiring layer can be formed by any known process, such as a subtractive process (i.e. etched foil process) or a full- or semi-additive process that employs electroplating and/or electroless plating. Alternatively, the wiring layer may be formed by depositing a thin metal layer by sputtering or chemical vapor deposition (CVD) and then etching unnecessary portions of the thin metal layer, or by printing with a conductive paste.

The material of the insulating resin layers can be selected according to its insulating properties, heat resistance, moisture resistance and the like. Examples of the material of the insulating resin layers include: resins, such as an epoxy (EP) resin, a polyimide (PI) resin, a bismaleimide-triazine (BT) resin and a polyphenylene ether (PPE) resin; composite materials, such as composites of any of the above resins and glass fibers (e.g. glass woven or unwoven fabric), composites of any of the above resins and organic fibers (e.g. polyamide fibers) and resin-resin composite materials formed by e.g. impregnating a three-dimensional network fluorocarbon resin (e.g. continuously porous polytetrafluoroetylene (PTFE)) with a thermosetting resin (e.g. an epoxy resin).

The process of forming the insulating resin layers is not particularly restricted. For example, each insulating resin layer can be formed by preparing a prepreg in which a base material is impregnated with a semi-cured resin, applying the prepreg and then curing the prepreg, or by preparing a sheet of insulating resin material and laminating the prepared sheet by thermo compression bonding.

The blind-via is a via formed in the insulating resin layer to establish electrical connection between the metal substrate and the wiring layer so that the metal substrate can also function as a ground layer or a power-supply layer. The blind-via does not necessarily make electrical connection between the metal substrate and the wiring layer nearest to the metal substrate. It is alternatively possible to form the blind-via so as to extend through one or more insulating resin layers between the metal substrate and the wiring layer farther away from the metal substrate.

The through-via is a via formed in the resin filler and the insulating resin layers to establish electrical connection between the wiring layer located on the first main surface and the wiring layer located on the second main surface while being kept insulated from the metal substrate. It is possible to provide another through-via that makes electrical connection between the wiring layers located on the first and second main surfaces while being electrically connected to the metal substrate.

The materials and forming processes of the blind-via and the through-via are not particularly restricted. For example, the blind-via can be formed by defining a blind hole in the insulating resin layer and then plating a wall of the blind hole with copper. Similarly, the through-via can be formed by defining a through hole in the resin filler and the insulating resin layers and then plating a wall of the through hole with copper. The blind hole and the through hole can be formed by e.g. by photoetching, drilling or laser machining.

To provide the through-via, the through hole is formed in the metal substrate and filled with the resin filler as mentioned above.

The process of forming the through hole in the metal substrate is not particularly restricted. The through hole can be formed by any known process, such as etching, laser machining or punching. When the metal substrate has a relatively large thickness, the through hole is preferably formed by etching, more preferably etching from both the first and second main surfaces of the metal substrate. Among various etching processes, photoetching is preferably used in order for the through hole to be formed with high accuracy. This allows improvement in manufacturing yield.

The material of the resin filler can be selected as appropriate according to its insulating property, heat resistance, moisture resistance and the like. Examples of the material of the resin filler include any resins usable as the material of the insulating resin layer or layers, such as an EP resin, a PI resin, a BT resin and a PPE resin. In view of cost and productivity, it is desirable to use the material of the insulating resin layers as the material of the resin filler. For example, the resin filler can be filled in the through hole of the metal substrate simultaneously with forming the insulating resin layer or layers on the copper coating.

The copper coating needs to be applied to the first and/or second main surface of the metal substrate on which the insulating resin layer is located. More specifically, when the insulating resin layer or layers are located on either one of the first and second main surfaces of the metal substrate, the copper coating is applied to the main surface on which the insulating resin layer or layers are located. When the insulating resin layers are located on both the first and second main surfaces of the metal substrate, the copper coating is applied to the first and second main surfaces. As described above, in the case where the through hole is formed in the metal substrate and filled with the resin filler, the copper coating is preferably applied to the inner surface of the through hole as well.

The copper coating is characterized as having the roughened surface. Herein, the term “roughened surface” is defined as a surface having fine geometrical irregularities of the order of micrometers formed therein throughout the surface so as to provide a sufficient effect of anchoring thereon the insulating resin layer or layers, the blind-via and the resin filler. More specifically, the roughness (arithmetic mean roughness) Ra of the roughened surface of the copper coating is generally controlled to 0.1 to 10 μm, preferably 0.1 to 5 μm, more preferably 0.5 to 3 μm. When the roughness Ra of the roughened surface of the copper coating is within the above-specified range, the roughened surface of the copper coating can produce a suitable anchoring effect. If the roughness Ra of the roughened surface of the copper coating is too high or too low, the roughed surface of the copper coating does not provide a suitable anchoring effect so that the adhesion between the metal substrate and the insulating resin layer or layers, the adhesion between the metal substrate and the blind-via and the adhesion between the metal substrate and the resin filler cannot be improved sufficiently.

The roughened surface of the copper coating is not necessarily of pure copper, and can be of any copper compound (e.g. copper oxide) or copper alloy.

The thickness of the copper coating is preferably smaller than the thickness of the metal substrate, more preferably smaller than or equal to one-fifth of the thickness of the metal substrate, most preferably one-tenth of the thickness of the metal substrate. More specifically, the thickness of the copper coating is preferably 5 μn or larger, more preferably 5 to 50 μm, most preferably 5 to 20 μm. Even when the thickness of the copper coating is made larger than necessity, the copper coating does not provide any further improvement in the adhesion between the metal substrate and the insulating resin layer or layers, between the metal substrate and the blind-via and between the metal substrate and the resin filler and causes deteriorations in cost and productivity. Herein, there may be thickness variations in the copper coating. When the thickness of the copper coating is less than 5 μm, the copper coating may not cover the metal substrate in places due to such thickness variations and fails to provide sufficient improvement in adhesion. In the case where the through hole is formed in the metal substrate, it is effective to control the thickness of the copper coating to 5 μm or larger so as to secure reliability at the edge of the through hole.

It is desirable that the copper coating is not so closely packed as a copper layer formed by rolling. For this reason, the copper coating is preferably formed by plating. The copper plating can be performed at low cost and be applied to any narrow hole so as to form the copper coating of sufficient thickness on not only the first and second main surfaces of the metal surface but also the inner surface of the through hole of the metal substrate. Further, the copper coating formed by plating is not so closely packed that the roughened surface can be relatively easily formed on the copper coating by any known copper-surface roughening treatment. Accordingly, the wiring board can be manufactured properly without a great increase in manufacturing cost. The plating can be exemplified by electroplating and electroless plating. The copper electroplating is rather preferred because of its high plating speed and low processing cost. By the use of such electroplating, the copper coating can be thus applied efficiently in a short time and at lower cost. In addition, the copper coating formed by the copper electroplating can attain a relatively high adhesion to the metal substrate

The roughened surface is formed by surface roughening the copper coating. The process of surface roughening the copper coating is not particularly restricted, and can be done by any known copper-surface roughening treatment, notably chemical surface roughening treatment. The surface roughening treatment usable in the present invention can be exemplified by: the processes in which a surficial portion of the copper coating is oxidized and eroded to form an acicular oxide, such as a black-oxide coating process (so-called blackening process) and a brown-oxide coating process; and the process in which an etchant is sprayed to dissolve a grain boundary of the copper coating, such as microetching. For electrical connection between the metal substrate and the blind-via, it is preferable to, when the surface of the copper coating becomes oxidized in the surface roughening treatment, reduce the oxidized surface of the copper coating so as to lower the electrical resistance at the interface between the copper coating and the blind-via.

It is noted that the corrosion of the copper coating occurs in any of the above surface roughening treatments. Accordingly, the thickness of the copper coating is preferably controlled to 10 μn or larger, more preferably 10 to 50 μm, before the copper coating is subjected to the surface roughening treatment. When the thickness of the copper coating is less than 10 μm before the surface roughening treatment, the copper coating may become less than 5 μm in thickness during and after the surface roughening treatment. As a result, there arises a possibility that the metal substrate becomes uncoated in places so that the adhesion between the metal substrate and the insulating resin layer or layers cannot be improved sufficiently.

In the case of providing the blind-via, the copper coating is preferably applied to the metal substrate without any insulating material e.g. an organic resin adhesive interposed between the metal substrate and the copper coating. When the insulating material is interposed between the metal substrate and the copper coating, the insulating material interferes with electrical conduction between the metal substrate and the copper coating. As a result, the metal substrate cannot suitably function a ground layer or a power-supply layer.

It is rather preferable to provide an undercoat layer made of a conductive metal other than copper between the metal substrate and the copper coating, although the copper coating can be applied directly to the metal substrate. The conductive metal usable for the undercoat layer can be exemplified by nickel, cobalt and chrome. Alternatively, the undercoat layer may be made of a specific conductive copper compound, such as copper cyanide. With such an undercoat layer provided between the metal substrate and the copper coating, it becomes possible to protect the copper coating from corrosion and, at the same time, possible to secure good adhesion between the metal substrate and the copper coating. In addition, the undercoat layer does not interfere with electrical conduction between the metal substrate and the copper coating so that the metal substrate can be suitably used as a ground layer or a power-supply layer by providing the blind-via. In the case of the metal substrate being a rolled plate made of a Fe—Ni alloy, for example, the undercoat layer is preferably made of nickel.

The thickness of the undercoat layer is preferably smaller than that of the copper coating, more preferably 0.1 to 5 μm, most preferably 0.1 to 1 μm. When the thickness of the undercoat layer is less than 0.1 μm, the undercoat layer does not perform its function properly. When the thickness of the undercoat layer is made larger than necessity to exceed 5 μm, the undercoat layer does not provide any further improvements in corrosion resistance and adhesion between the metal substrate and the copper coating and causes deteriorations in cost and productivity.

The undercoat layer can be formed by plating (such as strike plating) or any other thin metal film forming process (such as sputtering or CVD), as the undercoat layer is made much thinner than the copper coating.

By the above-described method, the wiring board can be easily and properly manufactured at low cost.

For the manufacturing of the wiring board, it would be convenient to provide in advance a substrate material by combining the above metal substrate and copper coating. In one useful combination as the substrate material, the metal substrate is a rolled plate made of a Fe—Ni alloy and having a thickness of 150 μm or larger; whereas the copper coating is applied to at least one of the first and second main surfaces of the metal substrate and having a thickness of 5 μm. In another useful combination, the metal substrate is a rolled plate made of a Fe—Ni alloy and having a thickness of 150 μm or larger and is formed with a through hole; whereas the copper coating is applied to both the first and second main surfaces of the metal substrate and the inner surface of the through hole.

The present invention will be described below in more detail with reference to the following specific embodiments. In the embodiments, like parts and portions are designated by like reference numerals, and repeated descriptions thereof are omitted.

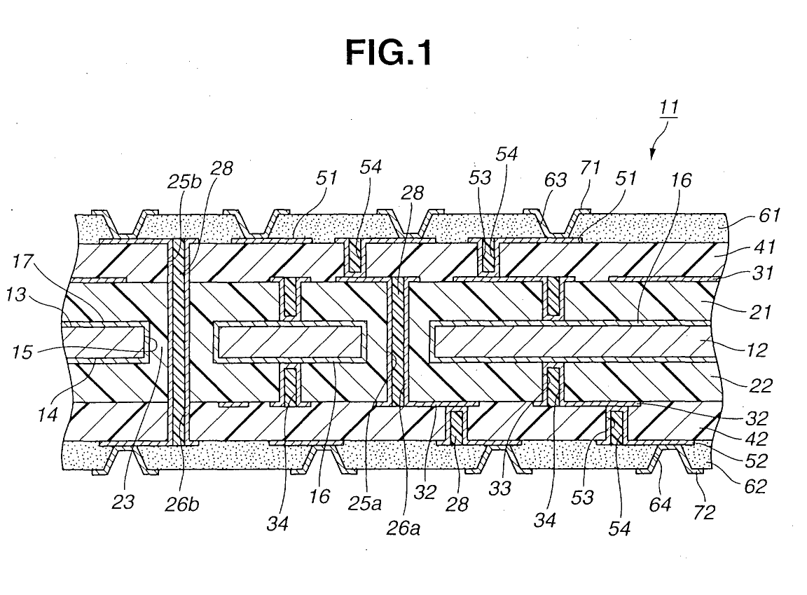

Firstly, a first embodiment of the present invention will be explained. As shown in FIG. 1, a wiring board 11 according to the first embodiment of the present invention comprises a metal substrate (as a core) 12 having main surfaces 13 and 14, an electrolytic copper coating 16 applied to the metal substrate 12, and build-up layers formed on the copper coating 16. The build-up layers include alternating insulating resin layers 21, 41 and 61 and wiring layers 31 and 51 located on the main surface 13 and alternating insulating resin layers 22, 42 and 62 and wiring layers 32 and 52 located on the main surface 14.

The metal substrate 12 is a rolled plate of Invar (a Fe—Ni alloy). The thickness of the metal substrate 12 is controlled to 0.25 mm. The metal substrate 12 defines therein a plurality of through holes 15 extending through the metal substrate 12 between the main surfaces 13 and 14. The diameter of each through hole 15 is 0.30 mm.

The copper coating 16 is uniformly applied to the whole of the metal substrate 12 (including the main surfaces 13 and 14 and inner surfaces of the through holes 15). The copper coating 16 has a roughened surface 17 formed thereon with a roughness Ra of about 1 μm. The roughened surface 17 is formed throughout the copper coating 16. The thickness of the copper coating 16 is approximately 15 μm after the roughened surface 17 is formed on the copper coating 16.

Each of the inner insulating resin layers 21 and 22 and the middle insulating resin layers 41 and 42 is made of a resin-resin composite material containing a continuously porous PTFE with an EP resin, and has a thickness of 50 μm. Each of the outer insulating resin layers 61 and 62 is made of a photosensitive EP resin, and has a thickness of 20 μm. The inner insulating resin layers 21 and 22 are formed on the copper coating 16 so as to abut on the roughened surface 17. The middle insulating resin layers 41 and 42 are provided on the inner insulating resin layers 21 and 22, respectively; and the outer insulating resin layers 61 and 62 are provided on the middle insulating resin layers 41 and 42, respectively.

Each of the inner wiring layers 31 and 32 and the middle wiring layers 51 and 52 is made of copper, and has a thickness of about 15 μm. The wiring layer 31 is arranged between the insulating resin layers 21 and 41, and the wiring layer 32 is arranged between the insulating resin layers 22 and 42. The wiring layer 51 is arranged between the insulating resin layers 41 and 61, and the wiring layer 52 is arranged between the insulating resin layers 42 and 62.

Blind holes 33 are formed in the insulating resin layers 21 and 22. The diameter of each blind hole 33 is controlled to 70 μm. Blind-vias 34 are formed on inner walls of the blind holes 33 so as to extend between the copper coating 16 and the wiring layers 31 and 32 for electrical connection between the metal substrate 16 and the wiring layer 31 and between the metal substrate 16 and the wiring layer 32. With this, the metal substrate 12 can be controlled to a predetermined potential (such as a ground potential or a power-supply potential) so as to be able to function as a ground layer or a power-supply layer.

Blind holes 53 are formed in the insulating resin layers 41 and 42. The diameter of each blind hole 53 is also controlled to 70 μm. Blind-vias 54 are formed on inner walls of the blind holes 53 for electrical contact between the wiring layers 31 and 51 and between the wiring layers 32 and 52.

Further, blind holes 63 and 64 are formed in the insulating resin layers 61 and 62 so as to taper down to the wiring layers 51 and 52, respectively. Pads 71 and 72 are formed on inner walls of the blind holes 63 and 64 so that the bottoms of the pads 71 and 72 are electrically connected to the wiring layers 51 and 52, respectively. Each of the pads 71 and 72 has a three-layer structure (including a copper plating layer, a nickel plating paler and a gold-flush layer) although not shown in the drawings. These pads 71 and 72 are joined to the terminals of an IC chip or motherboard (not shown) by e.g. soldering, thereby forming a so-called metal-core type semiconductor package.

Further, the through holes 15 are filled with a resin filler 23. The resin filler 23 is made of the EP resin of the above resin-resin composite material.

Through holes 25a are formed through the inner insulating resin layers 21 and 22 and the resin filler 23, although only one of the through holes 25a is shown in the drawings. The diameter of the through hole 25a is controlled to 0.15 mm. Through-via 26a are formed on inner walls of the respective through hole 25a for electrical contact between the wiring layers 31 and 32.

Through holes 25b are formed through the inner insulating resin layers 21 and 22, the middle insulating resin layers 41 and 42 and the resin filler 23, although only one of the through holes 25a is shown in the drawings. The diameter of the through hole 25b is also controlled to 0.15 mm. Through-vias 26b are formed on inner walls of the respective through hole 26b for electrical contact between the wiring layers 51 and 52.

In the present embodiment, the through-vias 26a and 26b are kept insulated from the metal substrate 12. It is alternatively to possible to electrically connect the through vias 26a and 26 to the metal substrate 12.

A plug 28 is placed in each of the vias 26a, 26b, 34 and 54. The plugs 28 are made of an EP resin.

The above-structured wiring board 11 can be manufactured by the following procedure.

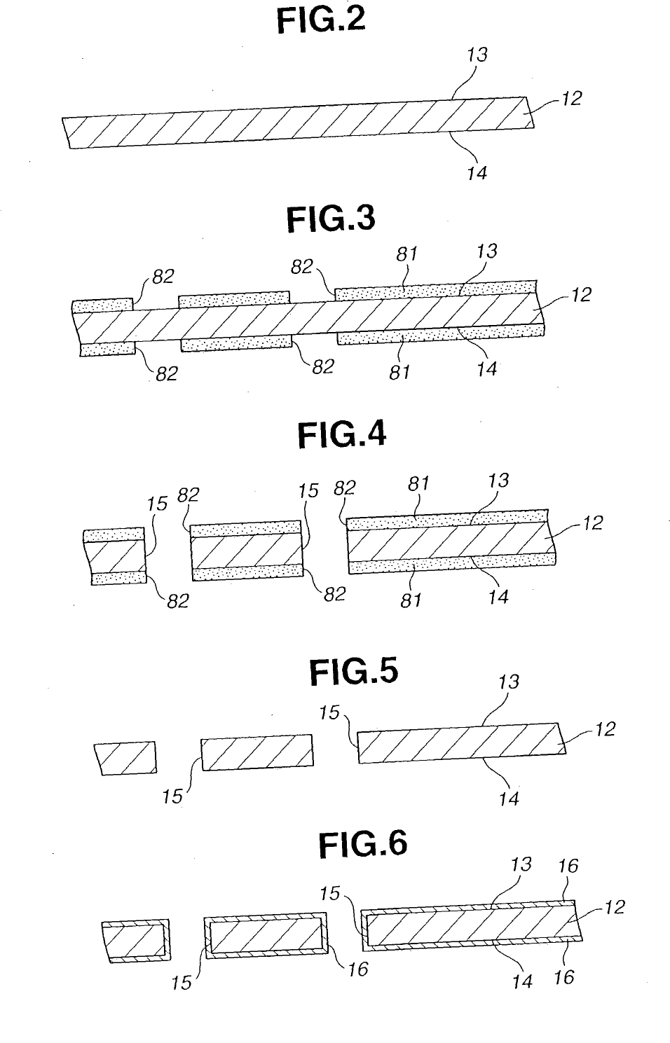

The metal substrate 12 is first prepared (see FIG. 2). Then, a mask 81 is formed in a certain pattern by applying a photoresist to the main surfaces 13 and 14 of the metal substrate 12 and subjecting the photoresist to exposure and development (see FIG. 3). Herein, the mask has openings 82 at positions where the through holes 15 are to be formed. With the use of a known etchant capable of dissolving a Fe—Ni alloy, the metal substrate 12 is etched from both the main surfaces 13 and 14 to thereby form the through holes 15 in the metal substrate 12 (see FIG. 4). The mask 81 no longer needed is dissolved and removed with a specific remover to expose the main surfaces 13 and 14 of the metal substrate 12 (see FIG. 5).

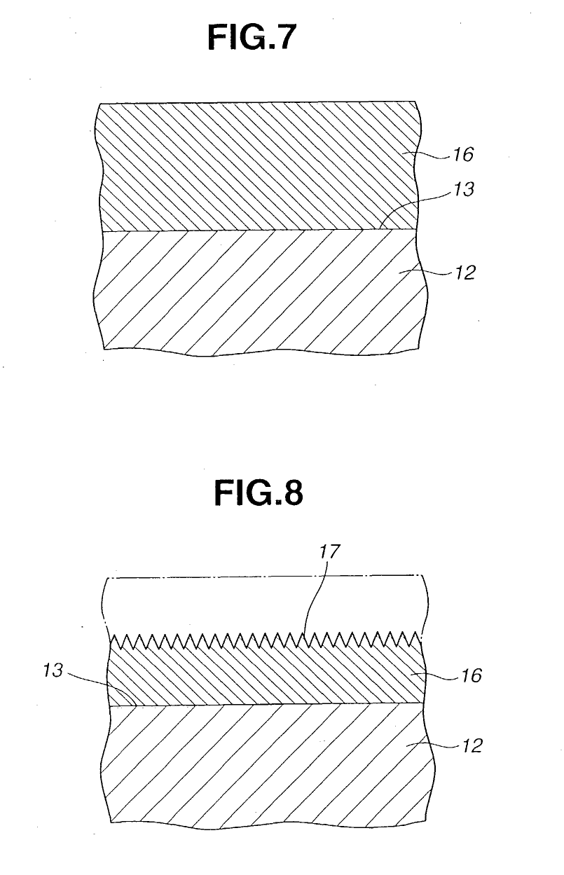

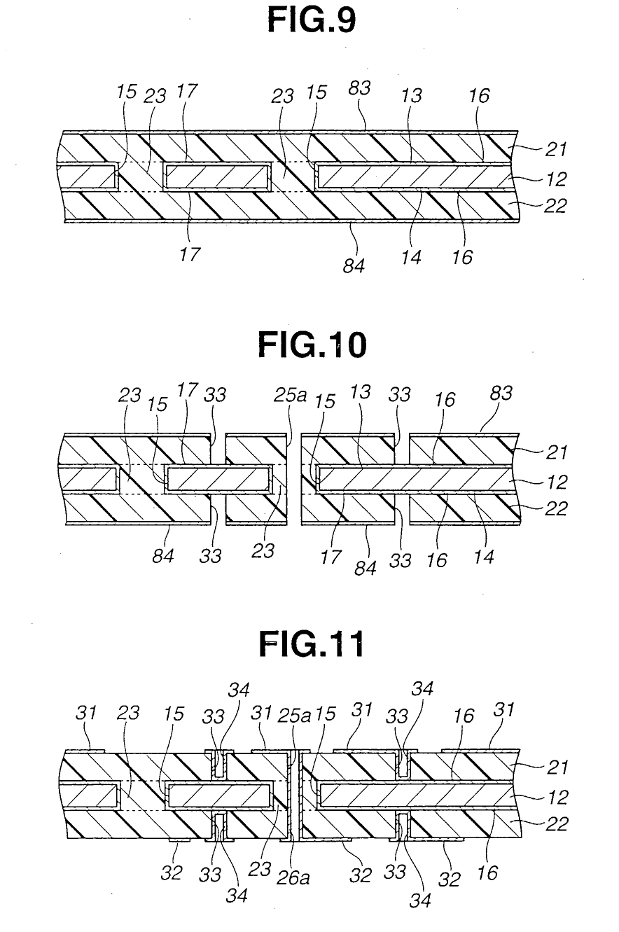

Next, the metal substrate 12 is given copper electroplating without any resist so that the electrolytic copper coating 16 is uniformly applied to the main surfaces 13 and 14 of the metal substrate 12 and the inner surfaces of the through holes 15 (see FIGS. 6 and 7). At this time, the copper coating 16 is not yet surface-roughened. Before the surface roughening treatment, the thickness of the copper coating 16 is controlled to 20 μm.

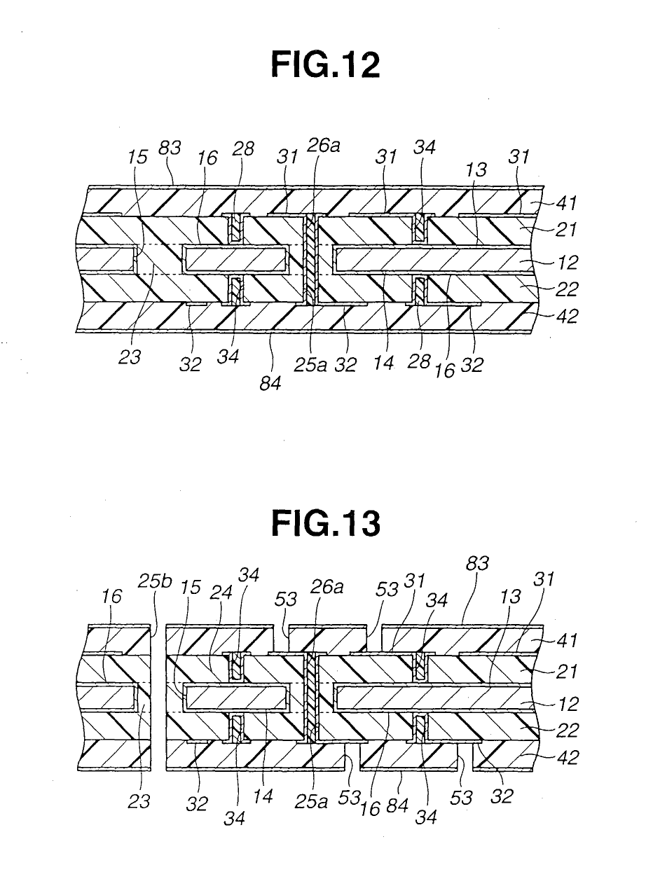

Then, the copper coating 16 is surface roughened by microetching. In the microetching, the top of the copper coating 16 is oxidized and eroded to form the roughened surface 17 on the copper coating 16 (see FIG. 8). The microetching can be done using a commercially available etching machine. The process of microetching is disclosed in Japanese Laid-Open Patent Publication No. 2000-282265, which is herein incorporated by reference. Upon the surface roughening treatment, the thickness of the copper coating 16 is reduced to approximately 15 μm.

For the formation of the insulating resin layers 21, 22, 41 and 42 and the resin filler 23, a prepreg (not shown) is prepared by impregnating a continuously porous PTFE with a semi-cured EP resin.

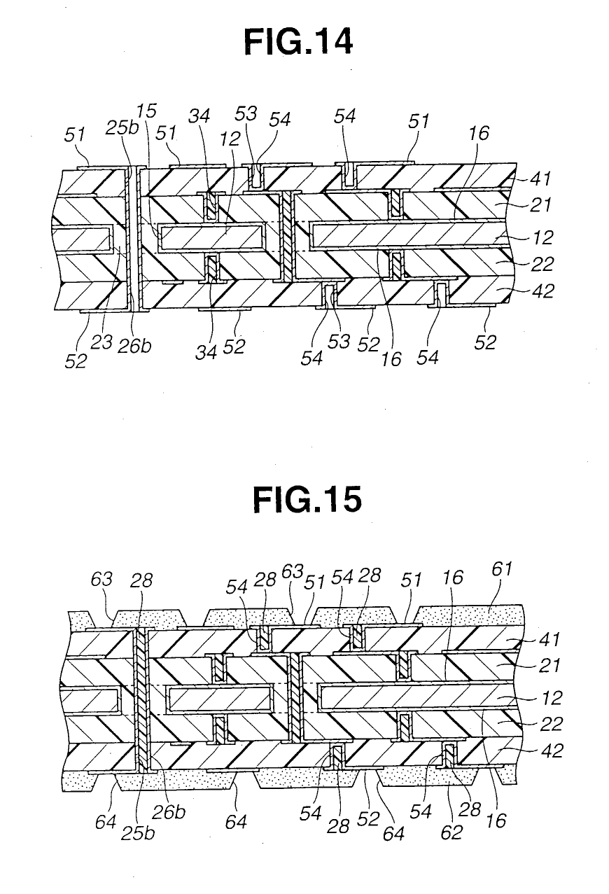

The prepreg is then applied to the main surfaces 13 and 14 of the metal substrate 12, and then, copper foil 83 and 84 each having a thickness of 20 μm is laid over the prepreg. The resultant laminate is subjected to thermo compression bonding under vacuum, thereby curing the prepreg to form the insulating resin layers 21 and 22 (see FIG. 9). During the thermo compression bonding, the EP resin exudes from the prepreg to provide the resin filler 23 in the through holes 15.

The thus-obtained laminate is subjected to laser machining to form the through hole 25a through the insulating resin layers 21 and 22, the resin filler 23 and the copper foil 83 and 84 as well as the blind holes 33 through the insulating resin layer 21 and the copper foil 83 and through the insulating resin layer 22 and the copper foil 84 (see FIG. 10). The laser machining is done using a YAG laser or a CO₂ laser. In the laser machining, it is necessary to control the laser output to the level that the metal substrate 12 and the copper coating 16 are not recessed and not pierced.

While the vias 26a and 34 are formed in the holes 25a and 33, the wiring layers 31 and 32 of predetermined patterns are arranged on the insulating resin layers 21 and 22, respectively. The vias 26a and 34 and the wiring layers 31 and 32 can be formed by any known process. In the present embodiment, the vias 26a and 34 and the wiring layers 31 and 32 are formed by the following process. First, electroless copper plating is given to the copper foil 83 and 84 and inner surfaces of the holes 25a and 33. Upon exposure and development, an etching resist of a predetermined pattern is formed on the electroless copper plating layer. While using the electroless copper plating layer as a common electrode, copper electroplating is given to openings of the etching resist and the inner walls of the holes 25 and 33. After the etching resist is dissolved and removed, unnecessary portions of the electroless copper plating layer and the copper foil 83 and 84 are removed by etching to form the vias 26a and 34 and the wiring layers 31 and 32 (See FIG. 11).

Then, the EP resin is filled into the vias 26a and 34, followed by curing the EP resin to provide the plugs 28 in the vias 26a and 34.

The previously prepared prepreg is applied to the insulating resin layers 21 and 22, and then, copper foil 83 and 84 each having a thickness of 20 μm is laid over the prepreg. The resultant laminate is subjected to hot pressing under vacuum, thereby curing the prepreg to form the insulating resin layers 41 and 42 (see FIG. 12).

The thus-obtained laminate is subjected to laser machining to form the through hole 25b through the insulating resin layers 21, 22, 41 and 42, the resin filler 23 and the copper foil 83 and 84 as well as the blind holes 53 through the insulating resin layer 41 and the copper foil 83 and through the insulating resin layer 41 and the copper foil 84 (see FIG. 13).

While the vias 26b and 54 are formed in the respective holes 25b and 53, the wiring layers 51 and 52 of predetermined patterns are arranged on the insulating resin layers 41 and 42, respectively (see FIG. 14). Herein, the vias 26b and 54 and the wiring layers 51 and 52 can be formed by any known process. For example, the process of forming the vias 26b and 54 and the wiring layers 51 and 52 is similar to the above-mentioned process of forming the vias 26a and 34 and the wiring layers 31 and 32 in the present embodiment.

The EP resin is filled into the vias 26b and 54, followed by curing the EP resin to provide the plugs 28 in the via conductors 26b and 54.

The photosensitive EP resin is applied to the insulating resin layers 41 and 42 and the wiring layers 51 and 52 and then subjected to exposure and development to form the insulating resin layers 61 and 62 in such a manner that the wiring layers 51 and 52 are exposed at the bottoms of the holes 63 and 64 (see FIG. 15).

The pads 71 and 72 are formed on the insulating resin layers 61 and 62, respectively, by a known process (e.g. the steps of electroless copper plating, etching, electroless nickel plating and then electroless gold plating), thereby completing the wiring board 11 as shown in FIG. 1.

In the above-structure, the roughened surface 17 of the electrolytic copper coating 16 serves as an anchor for anchoring thereon the insulating resin layers 21 and 22 so as to improve the adhesion between the metal substrate 12 and the insulating resin layers 21 and 22. It is therefore possible to prevent the insulating resin layers 21 and 22 from becoming separated from the metal substrate 12 and to secure proper electrical insulation. Also, the roughened surface 17 of the copper coating 16 serves as an anchor for anchoring thereon the blind-vias 34 and the resin filler 23 so as to improve the adhesion between the metal substrate 12 and the blind-vias 34 as well as the adhesion between the metal substrate 12 and the resin filler 23. The copper coating 16 does not interfere with electrical conduction between the metal substrate 12 and the blind-vias 34. It is thus possible to prevent the vias 34 from becoming separated from the metal substrate 12 and to securing proper electrical connection, and possible to prevent the resin filler 23 from becoming separated from the metal substrate 12 and to secure proper electrical insulation. Further, the wiring board 11 can be easily and assuredly manufactured by the above-mentioned method without an increase in cost.

Next, a second embodiment of the present invention will be explained. The second embodiment is structurally similar to the first embodiment, except that the copper coating 16 is not applied to the inner surfaces of the through holes 15.

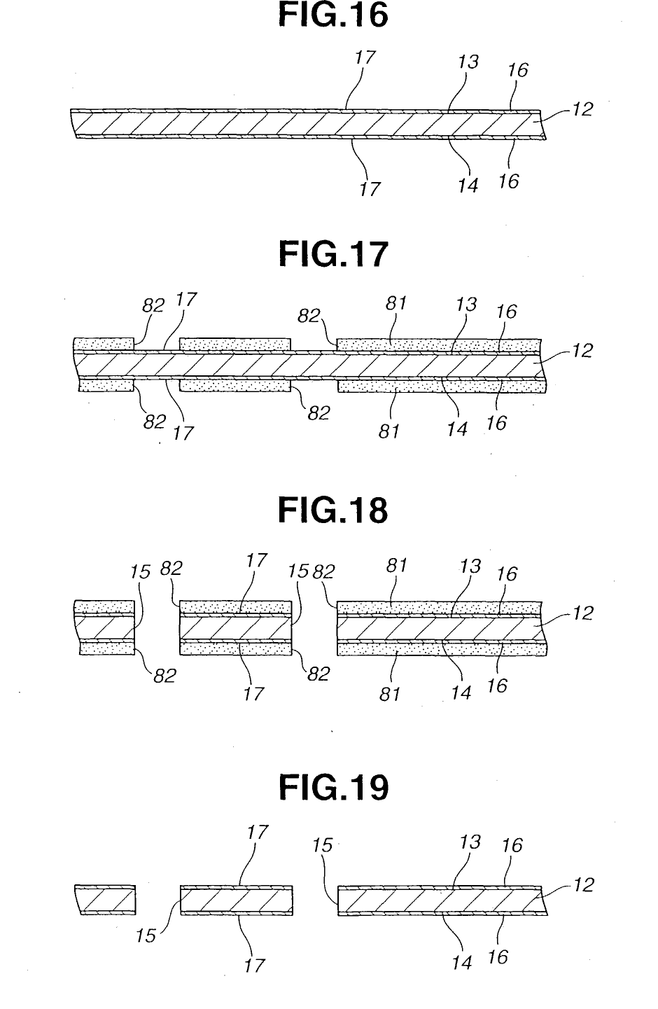

In the second embodiment, the metal substrate 12 is given copper electroplating uniformly to apply the electrolytic copper coating 16 before the through holes 15 are formed in the metal substrate 12. Then, the copper coating 16 is surface roughened by microetching to define the roughened surface 17 on the copper coating 16 (see FIG. 16). The process of microetching is the same as used in the first embodiment.

After that, a mask 81 is formed in a certain pattern by applying a photoresist to the copper coating 16 and subjecting the photoresist to exposure and development (see FIG. 17). Herein, the mask has openings 82 at positions where the through holes 15 are to be formed. With the use of a known etchant capable of dissolving copper and a Fe—Ni alloy, the metal substrate 12 is etched from both the main surfaces 13 and 14 to thereby form the through holes 15 in the metal substrate 12 (see FIG. 18). The mask 81 no longer needed is dissolved and removed with a specific remover, to expose the copper coating 16 (see FIG. 19). With this, the metal substrate 12 is provided with the copper coating 16 being applied to the main surfaces 13 and 14 of the metal substrate 12 but not to the inner surfaces of the though holes 15.

The insulating resin layers 21, 22, 41, 42, 61 and 62, the wiring layers 31, 32, 51 and 52 and the vias 26a, 26b, 34 and 54 are formed in the same manner as in the first embodiment.

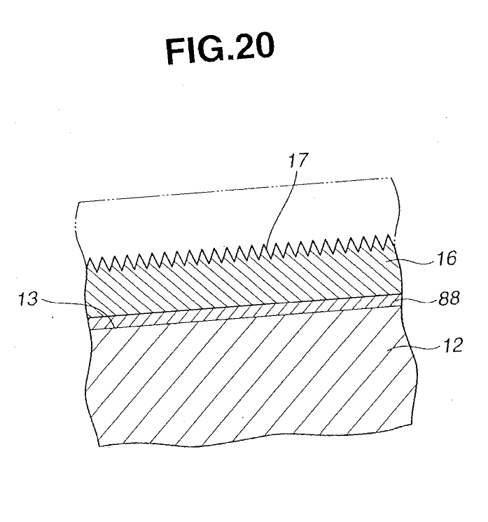

According to an modification of the first and second embodiments of the present invention, it is possible to provide an undercoat layer 88 of nickel electroplating or copper cyanide plating between the metal substrate 12 and the copper coating 16, as shown in FIG. 20, so as to protect the copper coating 16 from corrosion and to provide better adhesion between the metal substrate 12 and the copper coating 16 for higher reliability of the wiring board 11.

One or more additional metal substrates 12 may be provided so as to allow the wiring board 11 to be of lower expansion and to allow the metal substrates 12 to perform various functions for higher reliability and performance.

Although the wiring board 11 has the same number of layers on each of the main surfaces 13 and 14 of the metal substrate 12 in the above embodiment, different numbers of layers may be provided on the main surfaces 13 and 14 of the metal substrate 12.

It is also possible to form the wiring board 11 into a so-called “metal-base type wiring board” by providing the build-up layer on either one of the main surfaces 13 and 14 of the metal substrate 12.

The entire contents of Japanese Patent Application No. 2002-187255 (filed on Jun. 27, 2002) are herein incorporated by reference.

Although the present invention has been described with reference to specific embodiments of the invention, the invention is not limited to the above-described embodiments. Various modification and variation of the embodiments described above will occur to those skilled in the art in light of the above teaching. The scope of the invention is defined with reference to the following claims.

What is claimed is:

1. A multilayer wiring board, comprising:
a metal substrate having first and second main surfaces;
a copper coating applied to at least one of the first and second main surfaces of the metal substrate and having a roughened surface; and
an insulating resin layer formed on the roughened surface of the copper coating.

2. The multilayer wiring board according to claim 1, further comprising:
a wiring layer arranged on the insulating resin layer; and
a via extending through the insulating resin layer between the copper coating and the wiring layer.

3. The multilayer wiring board according to claim 1, wherein the copper coating has a thickness smaller than that of the metal substrate.

4. The multilayer wiring board according to claim 1, wherein the copper coating is a copper plating.

5. The multilayer wiring board according to claim 1, wherein the roughened surface of the copper coating has an arithmetic mean roughness Ra of 0.1 to 10 μm.

6. The multilayer wiring board according to claim 1, wherein the metal substrate is a rolled plate of metal or metal alloy having a thickness of having a thickness of 150 μm or larger.

7. The multilayer wiring board according to claim 1, further comprising an undercoat layer between the metal substrate and the copper coating, the undercoat layer being made of either one of nickel, cobalt and chrome and having a thickness smaller than that of the copper coating.

8. A multilayer resin wiring board, comprising:
a metal substrate having first and second main surfaces and defining therein a through hole extending between the first and second main surfaces;
a copper coating applied to the first and second main surfaces of the metal substrate and an inner surface of the through hole and having a roughened surface;
a plurality of insulating resin layers and wiring layers formed on the roughened surface of the copper coating to be located on the first and second main surfaces of the metal substrate, the insulating resin layers being interposed between the copper coating and the wiring layers or between the copper coating and the wiring layers and between the wiring layers;
a resin filler filled in the through hole;
a first via extending through the insulating resin layer between the copper coating and the wiring layer; and
a second via extending through the resin filler and the insulating resin layers between the wiring layer located on the first main surface and the wiring layer located on the second main surface while being kept insulated from the metal substrate.

9. The multilayer wiring board according to claim 8, wherein the copper coating has a thickness smaller than that of the metal substrate.

10. The multilayer wiring board according to claim 8, wherein the copper coating is a copper plating.

11. The multilayer wiring board according to claim 8, wherein the roughened surface of the copper coating has an arithmetic mean roughness Ra of 0.1 to 10 μm.

12. The multilayer wiring board according to claim 8, wherein the metal substrate is a rolled plate of metal or metal alloy having a thickness of 150 μm or larger.

13. The multilayer wiring board according to claim 8, further comprising an undercoat layer between the metal substrate and the copper coating, the undercoat layer being made of either one of nickel, cobalt and chrome and having a thickness smaller than that of the copper coating.

14. A method of manufacturing a multilayer wiring board, comprising:
preparing a metal substrate having first and second main surfaces;
applying a copper coating to at least one of the first and second main surfaces of the metal substrate;
surface roughening the copper coating to form a roughened surface on the copper coating;
forming an insulating resin layer to the roughened surface of the copper coating; and
arranging a wiring layer on the insulating resin layer.

15. The method according to claim 14, wherein the copper coating is formed by copper plating.

16. The method according to claim 14, wherein the copper coating has a thickness of 10 μm or larger before the surface roughening, and has a thickness of 5 μn or larger after the surface roughening.

17. A method of manufacturing a multilayer wiring board, further comprising:
preparing a metal substrate having first and second main surfaces;
defining a through hole in the metal substrate;
plating the metal substrate with copper to apply a copper coating to the first and second main surfaces of the metal substrate and an inner surface of the through hole;
surface roughening the copper coating to form a roughened surface on the copper coating;
forming insulating resin layers on the roughened surface of the copper coating so as to be located on both the first and second main surfaces of the metal substrate;
arranging wiring layers on the respective insulating resin layers;
filling a resin filler in the through hole;
providing a first via extending through the insulating resin layer between the copper coating and the wiring layer; and
providing a second via extending through the resin filler and the insulating resin layers between the wiring layer located on the first main surface and the wiring layer located on the second main surface while being kept insulated from the metal substrate.

18. The method according to claim 17, said defining comprising:
forming a mask on the metal substrate in a predetermined pattern;
after said mask forming, photoetching the metal substrate from both the first and second main surfaces to thereby define the through hole; and
removing the mask after said photoetching,
wherein said plating is done by electroplating after said removing, and said filling is done simultaneously with forming the insulating resin layers on the copper coating.

19. The method according to claim 17, wherein the copper coating has a thickness of 10 μm or larger before the surface roughening, and has a thickness of 5 μn or larger after the surface roughening.

20. A substrate material for a multilayer wiring board, comprising:
a metal substrate being a rolled plate of Fe—Ni alloy formed with a thickness of 150 μn or larger and having first and second main surfaces; and
a copper coating applied to at least one of the first and second main surfaces of the metal substrate, having a roughened surface and being formed with a thickness of 5 μm or larger.

21. The substrate material according to claim 20, wherein the roughened surface of the copper coating has an arithmetic mean roughness Ra of 0.1 to 10 μm.

22. A substrate material for a multilayer wiring board, comprising:
a metal substrate being a rolled plate of Fe—Ni alloy formed with a thickness of 150 μm or larger, having first and second main surfaces and defining therein a through hole extending between the first and second main surfaces; and
a copper coating applied to the first and second main surfaces of the metal substrate and an inner surface of the through hole and having a roughened surface.

23. The substrate material according to claim 22, wherein the roughened surface of the copper coating has an arithmetic mean roughness Ra of 0.1 to 10 μm.
